(19) United States
(12) Patent Application Publication
(10) Pub. No.: US 2010/0208431 A1
(43) Pub. Date: Aug. 19, 2010

(54) Patterned Composite Structures and Methods of Making the Same

(76) Inventors: Matthew P. Dugas, St. Paul, MN (US); Aland K. Chin, Sharon, MA (US)

Correspondence Address: DORSEY & WHITNEY LLP;INTELLECTUAL PROPERTY DEPARTMENT, SUITE 1500, 50 SOUTH SIXTH STREET, MINNEAPOLIS, MN, 55402-1498, US

(21) Appl. No.: 12/576,978

(22) Filed: Oct. 9, 2009

Related U.S. Application Data
(60) Provisional application No. 61/104,182, filed on Oct. 9, 2008.
(60) Provisional application No. 61/143,983, filed on Jan. 12, 2009.

(51) Int. Cl. H05K 7/20; F28F 7/00

(52) U.S. Cl. 361/709; 165/185

(57) ABSTRACT

The present disclosure relates to a patterned surface composite structure. The structure includes a first material having a specific coefficient-of-thermal-expansion and a second material having a different coefficient-of-thermal-expansion. The first material can be patterned with specific features and the second material may be located between those features, thereby forming areas having a coefficient-of-thermal-expansion between that of the first and second materials. A thermally emissive device, such as a laser diode, may be attached to a surface of the patterned composite structure.

### CROSS-REFERENCE TO RELATED APPLICATIONS

This application claims priority to U.S. Provisional Application No. 61/104,182, filed on Oct. 9, 2008, entitled “Patterned Cu-Diamond Composite Heat-Spreader,” and U.S. Provisional Application No. 61/143,983, filed on Jan. 12, 2009, entitled “Patterned Composite Materials,” the contents of which are herein incorporated by reference in their entirety.

### FIELD OF THE INVENTION

The present disclosure relates to structures and methods for providing thermal management for high-power electronic or thermally emissive devices. More particularly, the present disclosure relates to patterned composite structures that provide thermal management when used, for example, with devices that have a high thermal power density and that may be particularly sensitive to thermo-mechanical stress.

### BACKGROUND OF THE INVENTION

Many electronic and thermally emissive devices tend to degrade in performance and lifespan as the operational temperature of the devices increases. Consequently, some form of thermal management, or heat sinking, may be used to transfer heat from a high-power electronic device, for instance, into another body of material. The use of such “heat-spreader” technology has been increasing in several fields, such as but not limited to, fields using semiconductors or solid state lasers.

In integrated circuit technologies, for instance, the number of transistors that may be provided per unit area has increased over the years, according to Moore's Law, to well over 200 million transistors per CPU, thus increasing the need for heat dissipation in those devices. Other semiconductor devices, such as compound semiconductor high-powered laser diode devices, have relatively long and narrow lasing cavities that may be only a few micrometers thick within a relatively much larger semiconductor die, resulting in relatively extreme thermal densities in the laser cavity. Extreme thermal densities such as these can require effective and efficient thermal management.

Because the performance, reliability, and lifespan of thermally emissive devices can degrade as the operational temperature of the devices increases, or as a result of thermal instability, reduction of both the average and peak operating temperatures may be desirable or necessary. Temperatures may be reduced by attaching the thermally emissive device to a heat spreader, or heat spreader sub-mount, which may consist of a material with a relatively high thermal-conductivity (TC). In addition, the performance and reliability of the thermally emissive device can also degrade from mechanical stress resulting from a mismatch between the coefficient-of-thermal-expansion (CTE) of the device and the heat spreader.

Traditional metal matrix composite (MMC) heat spreader materials (e.g., Mo—W, Cu—W) and ceramic heat spreader materials (e.g., AN, SiC/Al, BeO) can be used to transfer heat away from a high-power thermal device. While these materials may be advantageous in that they may have a CTE that may be relatively close to that of the thermally emissive device, these materials offer relatively modest thermal conductivity (TC). Similarly, active heat sinks and reservoirs used for heat dissipation and/or management are known in the art; examples include larger fluidic cooling, working fluid phase change cooling, micro fluidics, and the electronic Peltier effect. Micro-channel coolers (MCCs) and thermo-electric coolers (TECs) are further examples of technologies that have been applied to thermally emissive devices.

Table 1 provides some typical materials used in the industry, along with the thermal and mechanical properties related to thermal management for each material.

TABLE 1

| Material | CTE (ppm/K) | TC (W/mK) |
|---|---|---|
| Semiconductor Materials | | |
| GaAs | 5.8 | 100 |
| InP | 4.6 | 68 |
| Si | 2.8 | 148 |
| Heat Sinking Materials | | |
| Cu—W (10-90) | 6.7 | 160 |
| Mo | 5.4 | 138 |
| W | 4.6 | 174 |
| Cu | 16.5 | 401 |
| Ag | 19.2 | 429 |
| Au | 47.5 | 317 |
| CVD Diamond | 1 | 1000 |
| Diamond | 1 | 2000+ |
| Cu-Diamond Particle | 6.7 | 470 |
| Composite | | |
| AlN | 3.5 | 100 to 200 |

In the high-power laser diode mount industry, for example, copper-diamond (Cu—W) sub-mounts are known for either mounting to an active micro-channel cooler or to a passive copper mount. As can be seen in Table 1, the Cu—W system may be a reasonable match for a GaAs semiconductor. However, Cu—W still has a 15% higher CTE than the GaAs device. While the traditional Cu—W heat spreader may have a relatively close CTE to that of GaAs, its thermal conductance (160 W/mK) is well below that of both copper (401 W/mK) and diamond (1000 to 2000 W/mK).

Diamond has a thermal conductivity (TC) of up to 2000 W/mK, depending on the specific form of diamond, which is approximately five times the TC of copper. Moreover, diamond has a thermal diffusivity (˜12.7 cm2/sec) that is eleven times that of copper (˜1.17 cm2/sec). The relatively high thermal diffusivity of diamond generally indicates that diamond can carry away heat without storing the heat. Thus, some properties of diamond such as its intrinsically high thermal conductivity and high thermal diffusivity may make it a good candidate material for use in a heat spreader; however, diamond has a relatively very low CTE. In fact, diamond has one of the lowest CTE values (1 ppm/K) of any material, including silicon, which is also very low (2.8 ppm/K). Additionally, diamond is not a relatively good electrical conductor. The low CTE and electrical conductivity of diamond makes it a poor matching material.

While diamond alone may not be a good matching material, diamond may be combined with other materials that have a higher CTE (e.g., Cu, Ag, Au, Mo, etc), resulting in a composite material with a CTE somewhere in between the CTE values of the individual materials. The composite material may also exhibit good electrical conductivity as a result of the inclusion of the metal. One relatively new idea in the art is the development of copper-diamond and silver-diamond particle composite materials. Such diamond particle composites are described, for example, in U.S. Pat. Nos. 6,987,318, 7,384,821, and 6,727,117, each of which is herein incorporated by reference in its entirety. The composites of the aforementioned patents, as well as other traditional diamond composite materials in the art of thermal management, are generally formed by powder metallurgical technologies or matrix composite techniques.

Accordingly, a need exists to provide a heat spreader structure with a relatively high thermal-conductivity and a generally relatively matched CTE with a thermally emissive device to which the heat spreader is to be attached. A need also exists for new structures that can be designed, or tuned, to meet the thermal management needs of various thermally emissive devices used in various applications.

### BRIEF SUMMARY OF THE INVENTION

The present disclosure, in one embodiment, relates to a patterned surface composite structure. The structure includes a first material having a specific coefficient-of thermal-expansion and a second material having a different coefficient-of-thermal-expansion. The first material can be patterned with specific features and the second material may be located between those features, thereby forming areas having a coefficient-of-thermal-expansion between that of the first and second materials.

The present disclosure, in another embodiment, relates to a thermally emissive structure. The structure includes a heat spreader structure having a first material with a specific coefficient-of-thermal-expansion and a second material having a different coefficient-of-thermal-expansion and a thermally emissive device mounted to the heat spreader. The first material of the heat spreader may be patterned with features and the second material may be located between the features, thereby forming a structure having a coefficient-of-thermal-expansion between that of the first and second materials.

The present disclosure, in yet another embodiment, relates to a method of making a patterned composite structure. The method involves depositing a first material having a specific coefficient-of-thermal-expansion, patterning features in the first material, and depositing a second material having a different coefficient-of-thermal-expansion over the first material. The method may further involve planarizing the structure such that a surface of the structure comprises areas of the first material and areas of the second material.

While multiple embodiments are disclosed, still other embodiments of the present disclosure will become apparent to those skilled in the art from the following detailed description, which shows and describes illustrative embodiments of the disclosure. As will be realized, the embodiments are capable of modifications in various obvious aspects, all without departing from the spirit and scope of the present disclosure. Accordingly, the drawings and detailed description are to be regarded as illustrative in nature and not restrictive.

### BRIEF DESCRIPTION OF THE DRAWINGS

While the specification concludes with claims particularly pointing out and distinctly claiming the subject matter that is regarded as forming the various embodiments of the present disclosure, it is believed that the disclosure will be better understood from the following description taken in conjunction with the accompanying Figures, in which:

FIG. 1 illustrates one method of making a patterned composite structure according to the present disclosure.

FIG. 2 illustrates another method of making a patterned composite structure according to the present disclosure.

FIG. 3 is a perspective view of a patterned surface composite heat spreader according to an embodiment of the present disclosure, made at wafer level, and made of a diamond coated wafer patterned into a field of diamond features in a matrix of metal and which has been planarized down to the surface of the diamond film layer.

FIG. 4 is a perspective view of a patterned surface composite heat spreader according to another embodiment of the present disclosure, made at wafer level, showing diamond patterning specific to a device layout with spaced regions that can be used as saw streets so that singulation does not require machining through the diamond material.

FIG. 5 is a plan view of a single patterned surface composite heat spreader in the form of a sub-mount, according to a further embodiment of the present disclosure.

FIG. 6 is a perspective view of a single patterned surface composite heat spreader in the form of a sub-mount according to another embodiment of the present disclosure, bonded to a larger thermal reservoir body in the style of a C-Mount.

FIG. 7 is a perspective view of a patterned surface composite heat spreader device according to yet another embodiment of the present disclosure, cut from the wafer, in the form of a sub-mount, bonded to a larger thermal reservoir body, in the form of a C-mount, showing a laser bonded atop the heat spreader.

FIG. 8 is a close-up perspective view of the patterned surface composite heat spreader device of FIG. 7, showing the front edge geometry of the laser.

FIG. 9a is a side section view of a critical geometry of the laser in relation to the sub-mount according to one embodiment of the present disclosure.

FIG. 9b is a side section view illustrating one possible angle inversion according to an embodiment of the present disclosure.

FIG. 9c is a side section view illustrating another possible angle inversion according to an embodiment of the present disclosure.

FIG. 10a is a perspective view of a laser row bar heat spreader attached to a large thermal reservoir in the style of a CS-mount according to an embodiment of the present disclosure.

FIG. 10b is a close-up perspective view of the laser row bar heat spreader of FIG. 10a with a laser attached according to an embodiment of the present disclosure.

FIG. 11a is an exploded perspective view of a patterned surface composite heat spreader wafer and a thicker copper wafer.

FIG. 11b is a perspective view of a patterned surface composite heat spreader wafer bonded to a thicker copper wafer.

FIG. 12a is a perspective view of a patterned surface composite heat spreader laminate bonded to a thicker copper substrate according to one embodiment of the present disclosure.

FIG. 12b is a perspective view of the patterned surface composite heat spreader laminate of FIG. 12a being partially patterned and etched with a laser process according to one embodiment of the present disclosure.

FIG. 12c is a perspective view of the patterned surface composite heat spreader of FIG. 12b deposited with copper, planarized, and made ready for device attachment according to one embodiment of the present disclosure.

FIG. 13 is a plan and side view of a heat spreader having anisotropic properties in the plane of attachment of the thermally emissive device according to one embodiment of the present disclosure

FIG. 14 is a plan view and side view of another embodiment of a patterned composite structure according to the present disclosure

### DETAILED DESCRIPTION

The present disclosure relates to novel and advantageous structures and methods for providing thermal management for thermally emissive devices. Particularly, the present disclosure relates to novel and advantageous patterned composite heat spreaders. The structures and methods described herein may have several applications, including for example, military applications ranging from high power laser weapons to LIDAR and range finders. There can also be large commercial potential for the structures and methods of the present disclosure, as laser diode bars may be used in the private sector for material processing. Furthermore, the structures and methods described herein may be used in applications with monolithic microwave integrated circuits (MMICs), power FETs, microprocessors, etc.

As discussed above, the prior art includes composite materials designed for thermal management comprising metal and diamond powder. Traditional metal-diamond powder composites, however, may be difficult to cut, machine, and/or form smooth surfaces and sharp edges, particularly when the diamond content is high. Additionally, metal-diamond powder composites may have unacceptably degraded mechanical stability after thermal cycling. In short, traditional metal-diamond powder composites may have process limitations when mechanically transforming the composites from the bulk state into a precision device level state that is essentially micro-mechanical in nature, for example, a device having a thickness less than about a millimeter with an edge radius on the micron scale. Similarly, traditional pure diamond heat spreader tabs also have limitations due to the extremely poor thermal match between the tabs and the thermally emissive device, requiring a conductive path of thin film material to be deposited around the edge to form a complete circuit, as used to drive laser diodes. However such a current path is typically highly resistive because of the long path and low cross-sectional area of the thin film conductor.

The various embodiments of patterned composite structures, or heat spreaders, described herein solve these problems and others. Some embodiments of the present disclosure include forming a metal-diamond composite with diamond patterns or features that may be arranged in a novel and advantageous manner and may allow for easier and more precise machining and lapping, may reduce surface roughness, and may enhance emitter edge definition. The heat spreaders of the present disclosure, in some embodiments may comprise electrically conductive materials that have a relatively high TC that may, for example, exceed that of copper. Further, in some embodiments of the present disclosure, a novel heat spreader may be advantageously designed to have a specific CTE that generally relatively matches or reasonably matches the CTE of the thermally emissive device to which it is to be mated. As used herein, the terms “generally relatively matches” or “reasonably matches,” when used with respect to CTE, may include what is understood in the art to be generally good matches or better between the CTE of two materials. In some embodiments the CTE may be tuned to the thermally emissive device of interest, such as semiconductors used for electronics and opto-electronics, including Si (silicon), GaAs (gallium arsenide), or InP (indium phosphide), for example. In some embodiments, the uniformity of both the TC and the CTE may be tuned from isotropic to highly anisotropic in the plane of device attachment. In some embodiments of the present disclosure tailored to a high-power laser-diode, the device emission-facet may be placed directly over a particularly patterned diamond region, as described in detail below, to selectively remove heat from generally the hottest part of the device into the highest TC sub-area. In some embodiments, the heat spreader may be used to transfer heat laterally from the thermally emissive device, vertically from the thermally emissive device, or a combination thereof. Some embodiments of the present disclosure described herein may provide reductions in, and in some cases substantial reductions in, the thermal resistance of the interface layer between the backside of a thermally emissive device and the next layer of the assembly, which may be a spreader or a heat sink.

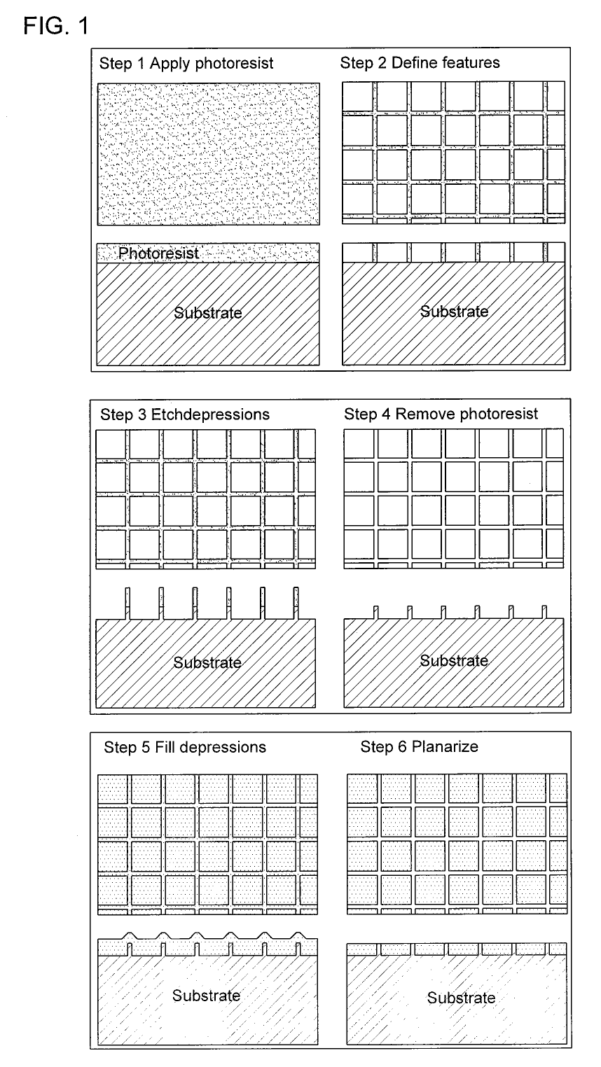

FIG. 1 illustrates one method of making a patterned composite structure of the present disclosure. As can be seen Step 1 of FIG. 1, in one embodiment, a heat spreader device may begin with a wafer substrate, such as but not limited to, a copper wafer, that may be any suitable size; however, in one embodiment, the wafer is approximately a few millimeters thick, similar to semiconductor device wafers. While wafers of a particular thickness are described, it will be recognized that any suitable wafer materials may be used in other thicknesses without departing from the scope of the present disclosure. In Steps 1-4, the wafers may be placed through an etching process, such as but not limited to, a photo-lithographic process that may be followed by etching or ion-beam milling, for instance, to define depressions or features. Particularly, in Step 1, a photoresist may be deposited on the wafer. The photoresist may be patterned to define the features that are to be patterned in the wafer substrate, as shown in Step 2. Then, the wafer substrate may be etched according to the photoresist pattern, as shown in Step 3. The photoresist may then be removed, leaving the wafer substrate with patterned features, as shown in Step 4. Etched patterns may include features of any shape, for example but not limited to, hexagons, circles, ellipses, square, rectangular or any other suitable shape or combinations thereof. In addition to these features, fiducial marks that may define wafer separation streets may be included. As shown in Step 5, these features may be filled with any suitable or desirable material or combination of materials using any suitable deposition technique, such as but not limited to CVD, sputtering, or electroplating, in some cases depending upon the material being deposited. The wafer may then be planarized, as shown in Step 6, to create a generally planar surface for the heat spreader.

Other methods of making a patterned composite structure of the present disclosure are possible and within the scope of the present disclosure. For example, in another embodiment a diamond-coated substrate or a diamond laminate attached to a substrate may be patterned to include the desired features into the diamond coat or laminate. Embodiments of the present disclosure may comprise any suitable substrate such that a film, for instance a diamond film, may be formed upon it. The substrate may comprise, for instance, silicon, molybdenum, tungsten carbide, silicon carbide, or any substrate that allows for film formation. In some embodiments, the substrate may comprise a part of the heat spreader. In other embodiments, the carrier substrate may be sacrificial and removed at a subsequent point in the process. The diamond coat/film or laminate may be deposited on a smooth or generally un-featured substrate or it may be deposited on a featured, or patterned, substrate. In the former case, patterning may be accomplished by any suitable means, for example but not limited to, by photolithography or laser ablation techniques. In the latter case, the features may be made by deposition into the features previously made into or onto the substrate. In some embodiments, the patterns or features may include facets that are substantially parallel to the wafer surface and facets that are substantially perpendicular to the wafer surface. The featured diamond substrate may have an adhesion layer and conductive seed layer deposited onto it. The adhesion layer and conductive seed layer may comprise a relatively thick, higher-CTE material, such as copper. Once the adhesion layer/seed layer has been applied, the surface may have a non-planar topology that may be subsequently planarized as desired. In other embodiments the non-planar topology may be filled in with a bonding material. Direct deposition of a comparatively lower CTE material onto a material with a comparatively higher CTE, or vice versa, and direct deposition of either a higher or lower CTE material onto a previously featured or patterned substrate are all fabrication combinations falling within the scope of the present disclosure.

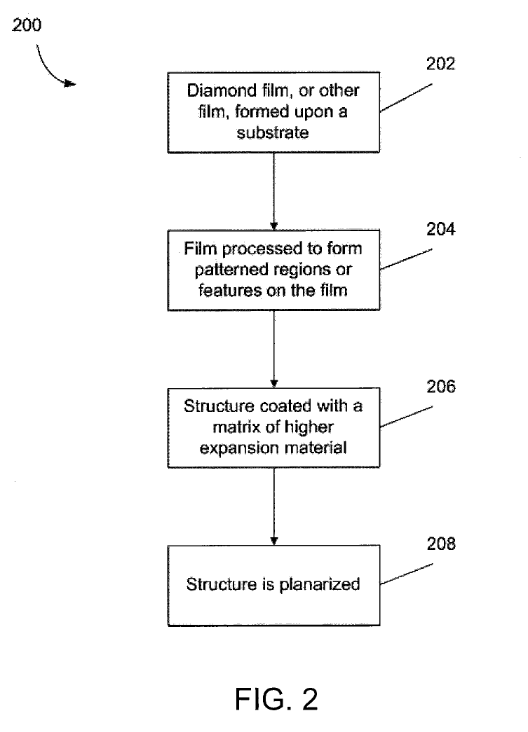

With particular reference to FIG. 2, a more detailed embodiment of a method 200 of making a patterned composite structure of the present disclosure is described. As shown in Step 202 of FIG. 2, in one embodiment, a film, such as but not limited to, a diamond film, may be formed upon a substrate. The diamond film may be formed by CVD or other suitable means, including but not limited to, lamination and assembly. The applied film may be relatively thin or thick, as desired. The film may be self supporting, or may be free standing were the film to be removed from the substrate. A thin film may be, for example, from about a few microns thick to about the submicron range of thickness. A thick diamond film may be, for example, from about a few microns thick to about a hundred or hundreds of microns thick. While these general ranges are provided, it will be recognized that the thickness of the film may be determined by the processing technology used and the design of the heat spreader desired for a specific application. Bulk systems, such as thick diamond laminates may also be used.

While some embodiments of a heat spreader are described with reference to diamond films, the present disclosure is not limited to the use of diamond films. Any combination of materials, including one material with a higher CTE, and one material with a lower CTE, for instance, may be used to form a patterned composite structure of the present disclosure and will be recognized as entirely within the scope of the present disclosure. For example, some materials may be more economical than diamond and may be used in certain applications, such as but not limited to, applications that have less critical thermal conductance requirements, but may still have thermal uniformity issues that need to be well managed. Accordingly, in some embodiments, a copper material may be used with a tungsten carbide substrate material and so on.

As shown in Step 204, once the film or laminate is formed upon or otherwise joined to the substrate, it may then be processed with photolithography and etching techniques or other suitable patterning techniques, such as but not limited to, direct laser ablation, to form patterned regions or features on the film or laminate. These regions may be connected or they may be isolated, or any combination of connectivity and isolation. In one embodiment, they may be islands with runners to transport heat. In some embodiments, the regions may be islands with facet matching runners to generally match the emitter facets of laser diodes, as will be described in more detail below. The regions may be uniform and periodic and/or they may have gradients of designs. The pattern may consist of individual elements which comprise a repeating pattern, or the pattern may not be formed from individual repeating elements, but rather from a plurality of different elements that form a pattern. The pattern may, in some embodiments, include no repeating individual elements, but instead have only a single non-repeating pattern. Individual elements may have any shape, such as, but not limited to, octagonal, hexagonal, diamond, rectangular, square, trapezoidal, circular, spherical, or any other suitable shape or combinations thereof. In thick laminate systems, as well as in thin wafer level systems, the pattern may be applied by laser ablation or direct machining. Furthermore, in wafer level systems, RIE and other etching techniques may also be used. Free standing diamond lamella, for example, may be laminated to final substrate structures for further processing such as laser etching or for temporary bonding and transfer purposes and other process steps. Bulk diamond laminates, for example, may therefore be processed in a planar sense by any suitable means. The diamond film may be patterned to generally fit a thermally emissive device's thermal signature. In this way, thermal gradients of the device may be mitigated, thereby increasing device performance and reliability. Moreover, in some embodiments, the shape and density of the diamond film patterns may also be made to generally relatively match the thermal signature of the device or to conduct heat laterally away from the device using relatively longer diamond runners. In some embodiments, the patterns in the diamond layer may be optimized to transfer heat in the lateral and/or vertical directions. In still other embodiments, the diamond patterns may be designed and used as electrical insulator regions and electrical lead traces, such that lead fan-outs may be placed upon them.

While patterns may comprise elements of any shape, as described above, in one embodiment, patterns in the diamond film formed using hexagons may provide a close packing system that may be relatively easy to analyze and may provide for substantially uniform diamond-to-diamond distances in the matrix material. The relative density and spacing between the features and materials may average the thermo-mechanical properties in a designable or tunable manner. The match may generally be most important at the surface of the heat spreader at the interface plane with the thermally emissive device. As the heat is transferred away from the thermal interface, the temperature lowers and the thermo-mechanical stress becomes less. Thus, the stress gradient in the direction normal to the plane of the thermal interface may become less critical as a function of the distance it is away from the thermally emissive device.

As shown in Step 206, once the patterned regions have been formed in the diamond, the structure may be coated with a matrix of higher expansion material, such as but not limited to copper, that may be deposited in-between and over the patterned regions formed in the diamond layer. Any deposition technique, such as but not limited to plating, may be used. In order to have a stable bond between the diamond layer and the high expansion matrix material, a carbide forming material, for example, such as chromium and titanium, may be used. Both chromium and titanium may form good bonds with a diamond layer, for example. Accordingly, one embodiment of the present disclosure may comprise a patterned diamond layer with a chromium and titanium seed layer or adhesion layer deposited over it. Over the seed layer, the matrix material may be plated up and over the entire structure. As the patterned diamond layer has a finite thickness, the matrix of Cu may generally replicate the surface structure of the patterned regions in the diamond layer.

The matrix used in embodiments of the present disclosure may be conductive or insulating or any combination thereof. A conductive matrix layer may be used, for example, because it may be more easily deposited and may make the entire structure electrically conductive. Further, a conductive matrix layer may have a relatively high thermal conductivity and a relatively high expansion so that when it is averaged with the diamond layer, the result may be a generally relatively matching CTE with a thermal emissive device of the desired application. A conductive metal, such as but not limited to copper, can provide a good material based on its CTE and TC properties and its ability to achieve a designed CTE with a relatively high TC when combined with diamond.

In certain embodiments of the present disclosure, the patterned composite can take advantages of two concepts alone or in combination. The first concept includes that of mixing high and low expansion materials to achieve a generally relatively matching or generally reasonably matching CTE to a particular thermally emissive device material. The second includes that of using planar fabrication techniques to make the patterned composite structures at either wafer level or at a more discrete level. With the use of precise planar semiconductor fabrication techniques in combination with thin or thick diamond films, the heat spreader in some embodiments of this disclosure may be made to generally relatively match the CTE and thermal profile of the thermally emissive device to which it will be attached. Another result of the planar processing is that each of the diamond layer features may have a controllable size, and the diamond layer may have facets that are substantially parallel to the substrate plane and facets that are substantially perpendicular to the substrate plane.

The planarity and perpendicularity of the diamond facets may have significant device application advantages. For example, the planar facets may form a relatively large area mechanical lapping stop that may be a useful process feature in any subsequent planarization process. Second, the perpendicular facets may form a good edge lap stop and edge definition feature in subsequent device level or row bar level processing, or for example, as with an edge emitting laser diode. This may result in a relatively sharp edge radius of the diamond facet edge of the heat spreader where the laser emitter facet is abutted into the system, as described further below. This edge facet, with a very small radius between the planar and perpendicular facets, may result in improved performance when heat sinking an edge emitting laser.

As shown in Step 208, once the matrix material has been deposited on the patterned film-coated substrate, the entire wafer may then be planarized to a generally flat surface. Planarization may stop in the copper layer, for instance, or it may stop upon or after reaching the diamond layer. In one embodiment, the planar diamond facets may form a good mechanical stop for a planarization process.

In some embodiments of the present disclosure, a bonding agent may be applied between the thermally emissive device and the heat spreader. While the figures described and referenced below may not show the bonding agent layer, it will be recognized that the bonding agent may be applied to each of the embodiments of the present disclosure. The bonding agent may be any suitable thin film or thin film stack deposited on at least one of the surfaces to be bonded. One such bonding agent film may comprise, for instance, a gold-tin eutectic or other similar thin film system that has suitable wetting and/or bonding characteristics. Any suitable bonding agent that is compatible with the two mating surfaces may be used and is within the scope of this invention. Non-thin film systems may also be used, such as brazing forms and foils, such as Au—Ge, or solders and other bulk forms, for example.

The design flexibility of the present disclosure allows for anisotropic and isotropic designs, as described in more detail below. In some applications, the degree of isotropy of the thermal properties may be locally varied in the bonding plane between the thermally emissive device and the heat spreader. In other applications, an isotropic design may be the most favored. In the example of a high power laser diode, the front facet generally has the largest thermal load, which can be accommodated for in the designs of the present disclosure. Similarly, with regard to other thermally emissive devices, the novel heat spreaders of the present disclosure may be designed to accommodate local high-temperature regions within the body of the device.

The figures provided herein are schematic only, and the size and density of the patterned regions in the diamond layer are not limiting. Likewise, the thermally emissive devices depicted in the figures are schematic and meant to be only generally descriptive of any particular device used in conjunction with the heat spreader.

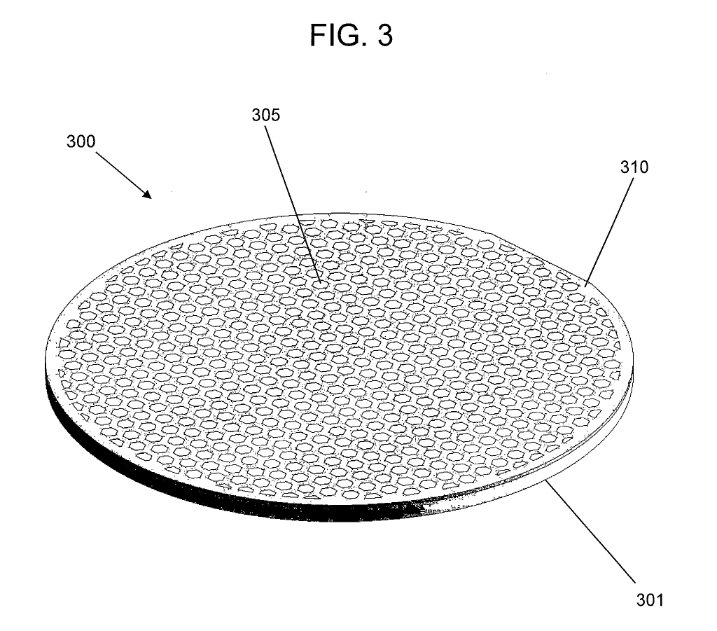

FIG. 3 shows one embodiment of a patterned composite heat spreader at a wafer level 300 according to the present disclosure. In this embodiment, a wafer substrate 301 comprised of, for example, silicon, may be coated with a layer of diamond that has had a pattern 305 etched into it. A metal matrix material 310 may be applied to the patterned diamond layer 305. The entire wafer system 300 may be planarized, as shown, down to the diamond film surface. As the diamond layer may be harder than the metal matrix material, the diamond may form a good mechanical lap stop, if for example lapping or CMP is used for the planarization. Planarization may also be achieved through machining the system or by using a combination of machining and lapping. The planarization may or may not proceed down to the diamond layer, depending on the intended application and/or the deployment technique used. FIG. 3 does not show a carbide forming seed layer, but such a layer may be included in embodiments of the present disclosure. A seed layer may be advantageous for a plating operation, for instance, but may not be advantageous for a sputtering operation, for instance.

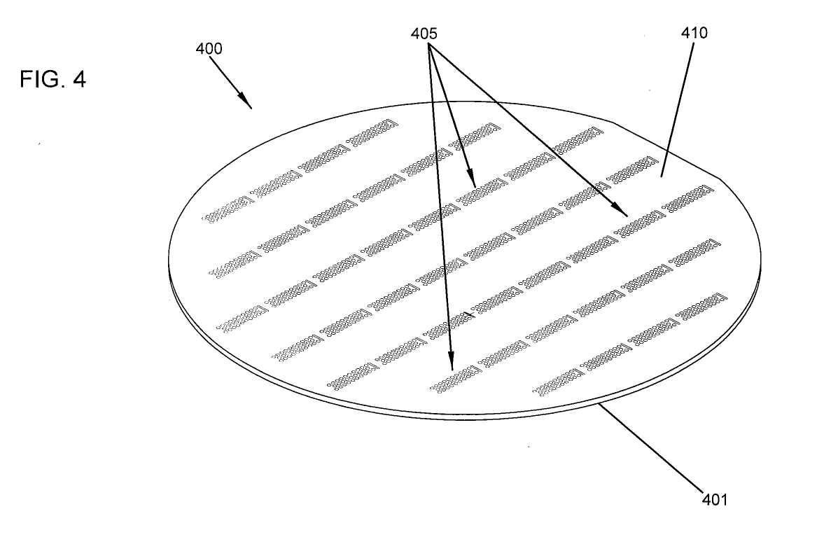

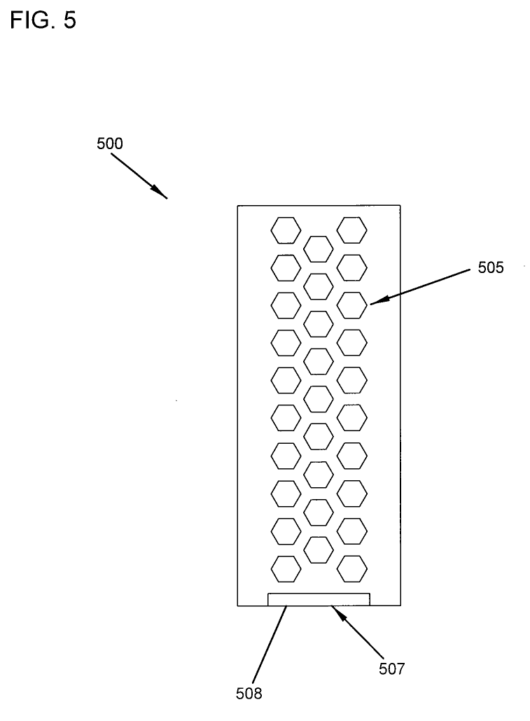

FIG. 4 shows one embodiment of a wafer system 400 according to the present disclosure comprising a substrate 401 that has a diamond film deposited on it with a pattern design of several heat spreaders 405, each for matching a thermally emissive device, such as a laser device, for example. Accordingly, FIG. 4 illustrates one embodiment of mass producing heat spreaders according to the present disclosure. In FIG. 4, several heat spreaders 405 are shown with spaces of copper matrix 410 located in-between the diamond patterns 405. The spaces of copper matrix 410 may also serve as cutting regions, or saw streets, such that the diamond does not have to be machined through during the dicing process. The patterned diamond regions may be in, for example, about the 20 um range, though patterned diamond regions of smaller and larger sizes are to be considered fully within the scope of the invention. FIG. 4 shows a uniform pattern comprised of repeating hexagons etched into the diamond layer 405; however, other patterns of other repeating shapes or combinations of shapes may be used, as described above. FIG. 5 shows an embodiment of one heat spreader device 500 taken from, for example, the wafer 400 of FIG. 4. Alternatively, a device similar to that shown in FIG. 5 may be made of thicker diamond laminate in a similar fashion.

Generally, the temperature of the front facet region of a high-power laser-diode (˜10-20 μm) may be significantly higher than that of the bulk due to surface recombination at the facet. The hot facet region may degrade device performance by increasing the optical absorption of the laser cavity. As the surface recombination increases with device operation, the device may eventually degrade by catastrophic optical damage where the front facet locally reaches the melting temperature of the semiconductor. Device performance and reliability may be improved in some embodiments of the present disclosure by reducing the temperature of the front facet region. Accordingly, in one embodiment, as shown in FIG. 5, a front diamond feature 507 and facet 508 of the device specific diamond pattern 505 may be provided so as to correspond to the front facet region of a laser diode emitter, for example, to provide an increased area of diamond near the front facet region of the laser diode emitter. While a rectangular diamond feature 507 is shown, it is recognized that any suitably sized and shaped region may be used for the front diamond feature 507 and facet 508 of the device specific diamond pattern 505.

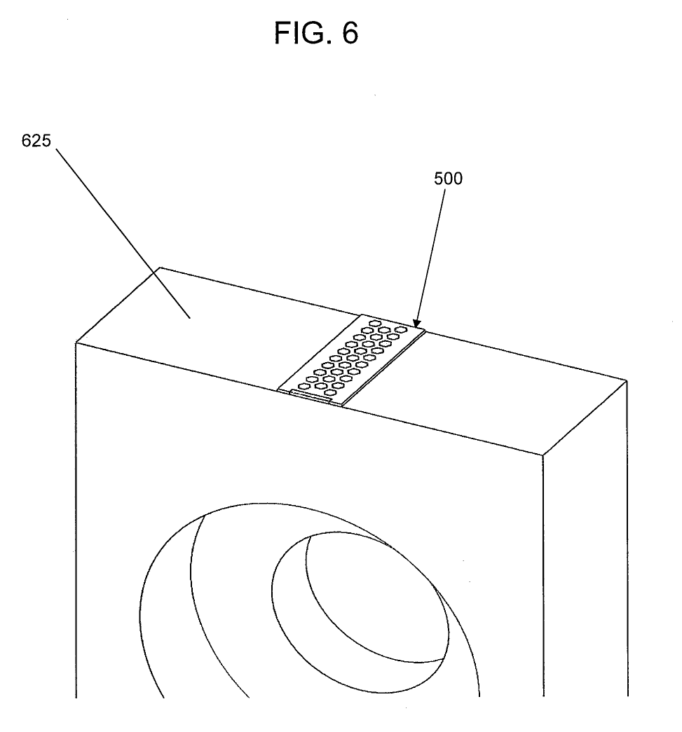

FIG. 6 illustrates a heat spreader 500, such as one that may be made by methods described above and shown in FIG. 5, bonded to a bulk copper heat sink 625 in the form of a C-mount, in accordance with one embodiment of the present disclosure. The heat spreader device 500 may be bonded to the heat sink 625 by any suitable means, and in some embodiments, such that the thermal impedance between the heat spreader and the heat reservoir mount is not limiting.

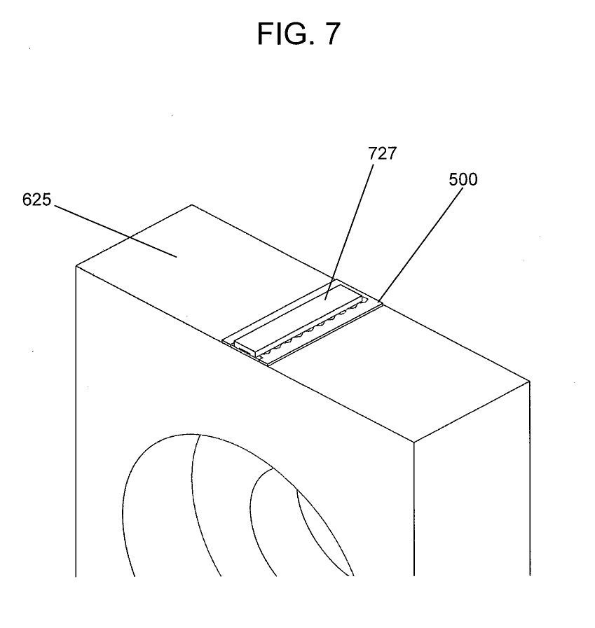

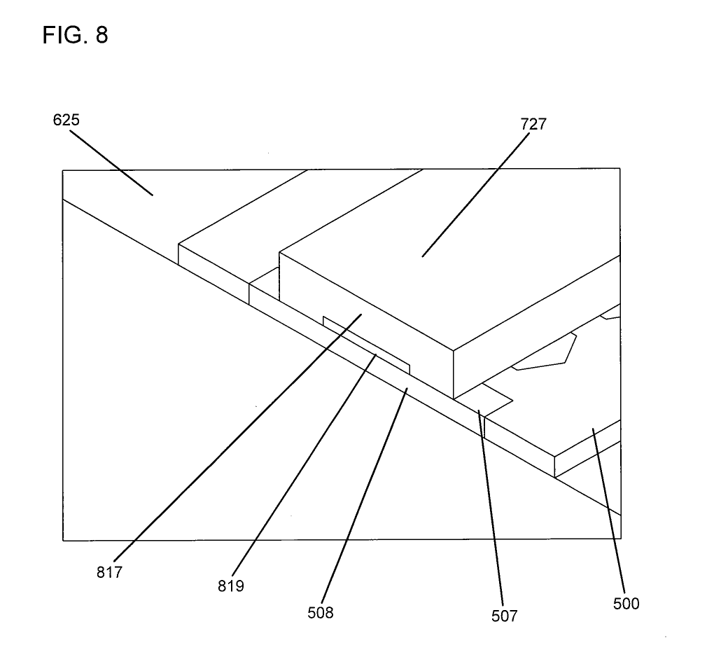

FIGS. 7 and 8 illustrate a composite heat spreader 500 according to an embodiment of the present disclosure, showing a thermally emissive device 727, such as but not limited to, a laser, bonded atop the heat spreader. FIG. 7 also illustrates an example embodiment of a composite heat spreader specifically designed to reduce the temperature of the front facet region of, the thermally emissive device. The system shown in FIG. 7, generally includes a laser diode 727 bonded to a heat spreader 500, which in turn is bonded to the heat sink 625. The body of the heat spreader 500 may be made in accordance with previously described embodiments, for example, such that it may have a relatively high TC yet generally relatively match the CTE of the laser diode. However, at the front edge of the heat spreader 500, a region 507 of diamond may be included, and which may be, for example but not limited to, about 20 μm-wide. The region 507 may locally increase the TC in the area of the region. As shown in FIG. 8, the facet 817 of the laser 727, which may include a co-planar facet subsection front emitter region 819, may be generally aligned to the facet 508 of the heat spreader 500. The thermal signature of a laser is generally such that the laser is the hottest up and down the lasing cavity region, and the lasing region is generally the hottest at the front and rear mirrors. The front portion of the rectangular patterned diamond region 507 and facet 508 may reduce the non-linear heat distribution of the laser channel and emitter region. The diamond region 507 associated with diamond facet 508 may remove more heat on this boundary formed at the intersection of the laser 727 and heat spreader 500. In one embodiment, the diamond facet 508 proper may provide a sharp edge that may generally align with the emitter facet, such that there may be substantially no portion of, or only a very minimal portion of, the laser channel that may not be in thermal contact with the heat spreader 500.

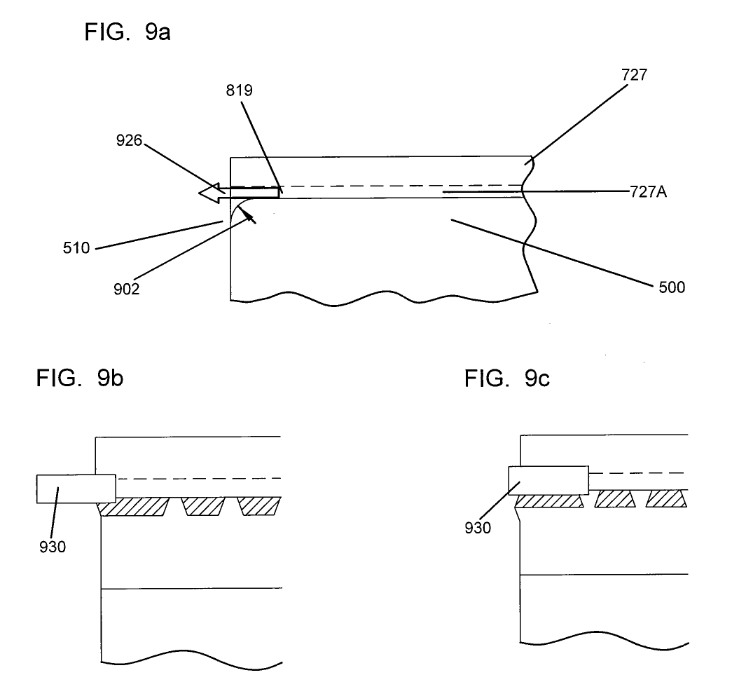

FIG. 9a depicts an embodiment of a cross-section of a laser 727 and heat spreader 500, illustrating the emitter facet 819. In one embodiment, in a heat spreader sub-mount for a diode laser, the front edge 510 of the heat spreader may ideally be generally straight with a minimum radius 902, and the laser emitter facet 819 may be generally parallel to the front edge 510 of the heat spreader. Traditional radius specifications of a sub-mount are typically in the range of 15 um or less, and sometimes are 5 um or less. The industry would prefer to have 2 um or less. As stated above, perpendicular diamond layer facets, according to some embodiments of the present disclosure, may result in a relatively sharp edge radius of the diamond facet edge 510 of the heat spreader where the laser emitter facet 819 is abutted. This edge facet 510, with a very small radius between the planar and perpendicular facets, may result in improved performance when heat sinking an edge emitting laser. According to a further embodiment of the present disclosure, the laser 727 may be moved back on the sub-mount in order to move away from the radius 902. The divergent laser beam 926 may hit the sub-mount when the laser cavity 727A is mounted face down and the epitaxial grown laser cavity 727A is relatively thin.

In further embodiments, as shown in FIGS. 9b and 9c, inversions of the edge profile of the heat spreader may be made using planar processing techniques. More particularly, in some embodiments, planar process technology according to the present disclosure may provide facets 930 that have relatively sharp boundaries as shown in FIGS. 9b and 9c. The inverted wall facet 930 as shown FIG. 9b, for example, in one embodiment may be provided by the wafer or die being flipped and attached to the thermal reservoir mount. The diamond front particle, in combination with its very sharp facet 930, may provide a relatively optimum boundary condition for a laser diode emitter facet. The slight non-verticality of the diamond facet 930 may be provided through the etching process. One advantage of some embodiments of the present disclosure may be that the diamond facets of all the patterned diamond particles, regardless of the specific shape of the particles, may be formed such that they are substantially perpendicular and parallel to the plane of the wafer and hence form relatively good process stops and sharp edges.

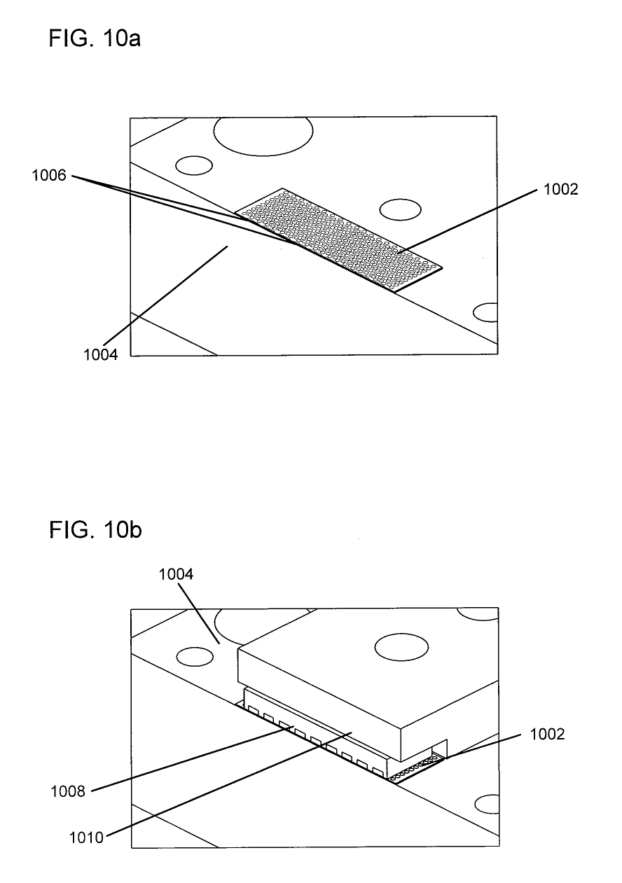

FIGS. 10a and 10b illustrate how embodiments of the present disclosure may be used in conjunction with an application of laser row-bars. In one embodiment, a patterned composite row bar heat spreader 1002 may be mounted to a thermal reservoir 1004 in the form of a CS-mount. The heat spreader 1002 may have a plurality of diamond facets, or regions 1006 of diamond, as described above. A laser row bar 1008 may be mated to the heat spreader 1002. In one embodiment, the laser 1008 may be attached to the row bar heat spreader with a film of AuSn eutectic, for example. The laser row-bar emitter facets 1010 may be placed in a precision manner with the emitter edge facets 1010 proximate to the diamond facets 1006.

It is not necessary for the heat spreader embodiments of the present disclosure to use a diamond facet on the leading edge; however, this is one of the embodiments possible. Edge emitting lasers may take advantage of a matching edge facet, while other devices such as monolithic microwave integrated circuits (MMICs) may not share a thermal profile that suitably takes advantage of such an embodiment of the present disclosure. The laser diodes and laser diode row bars as shown in FIGS. 8 and 10, may also take advantage of thick diamond laminates in the 200 um to 400 um thickness range, rather than being processed from wafer level diamond composite materials.

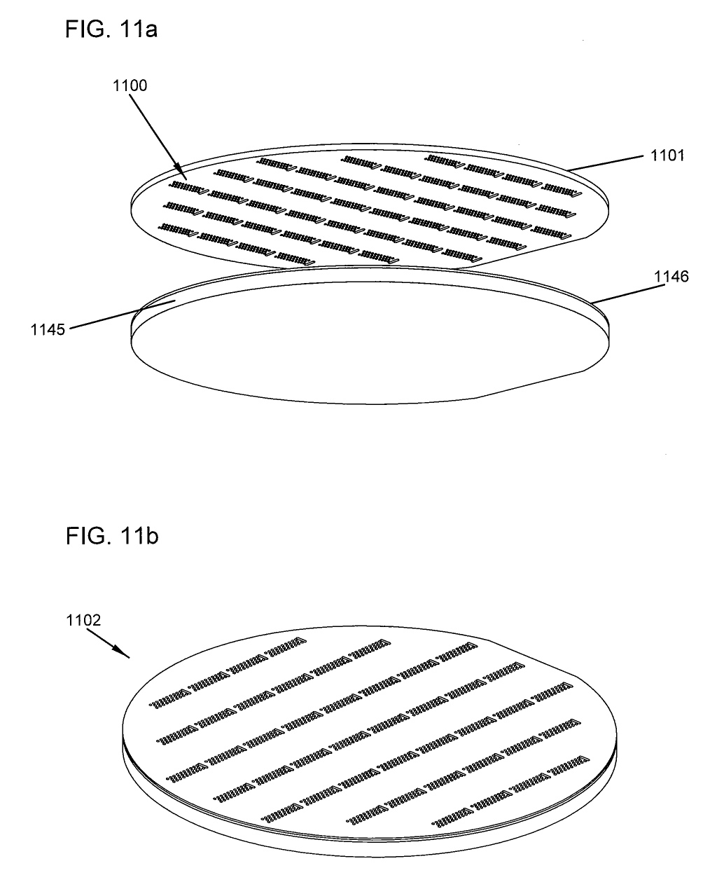

In some embodiments of the present disclosure, wafer bonding may be used in combination with the other aspects of this disclosure. For example, in one embodiment, a mechanically thin wafer of patterned surface composite material structures may be made thicker by mating it with a carrier substrate. For example, FIG. 11a shows an embodiment of a patterned surface composite heat spreader wafer 1100 in an exploded view with a mating copper wafer 1145 with a bonding agent 1146 that may be, for example but not limited to, a thin film or a foil form. A compound wafer 1102, shown in FIG. 11b, may result from combining the heat spreader wafer 1100 and the mating copper wafer 1145 with the bonding agent 1146. In the case of a diamond copper patterned surface composite heat spreader, the carrier wafer may be, for instance but not limited to, a copper wafer that may be, for example, approximately 1 mm in thickness. It will be recognized, however, that any appropriate material for the wafer or wafer thickness may be used. After the wafer-to-wafer bonding, the silicon 1101 of wafer 1100 may be removed, leaving the patterned diamond regions on the copper wafer. In such an embodiment, the silicon substrate is sacrificial.

The compound heat spreader wafer 1102 may be singulated into mechanically stable sub-mounts, as described above. As the sub-mounts may then be bonded to a larger copper mount system, in some embodiments, a AuSn eutectic layer, or other similar bonding layer, may be deposited at the wafer level before singulation. Additionally, the backside of the wafer 1102 may be deposited with a bonding agent, such as but not limited to, AuGe, AuSn, or Ag.

The compound wafer 1102, as shown in FIG. 11b, comprises but one deployment option contemplated by the present disclosure. Another deployment option, in accordance with another embodiment of the present disclosure, is to singulate, or slice, the prime wafer 1100 into separate heat spreader structures, which may then be attached directly to a larger copper mount, for example, with the substrate material, for example silicon, being subsequently removed. In yet another deployment option of the present disclosure, the primary patterned surface composite wafer 1100 may be directly bonded to a wafer of devices, such as but not limited to, a wafer of integrated circuits and then the entire assembly may be singulated. Also, in further embodiments of the present disclosure, the heat spreaders may be used at die level to bond with integrated circuit devices at die level. It will be recognized that the present disclosure encompasses both wafer level and die level heat spreaders.

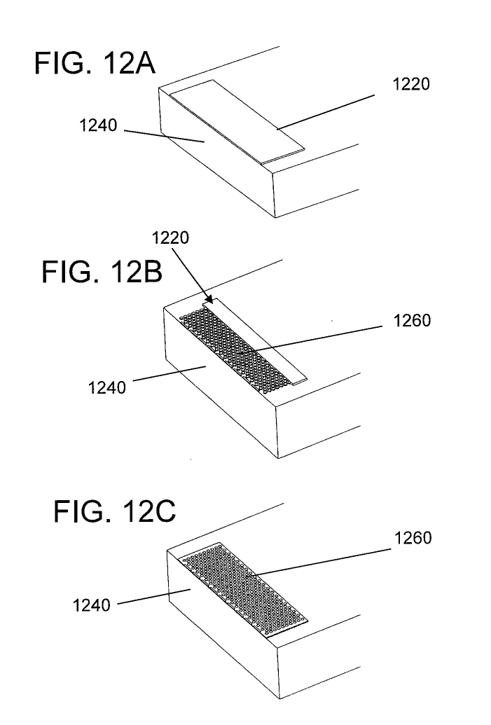

In another embodiment, FIGS. 12a-c show a free standing thick film diamond laminate process, analogous to a wafer lever process. However, these laminates may be up to about 400 um in thickness. In one process, a laminate 1220 may be bonded to the substrate 1240 as shown in FIG. 12a. As shown in FIG. 12b, the laminate 1220 may then be laser etched with a pattern 1260, such as the patterns discussed above. Then, the etched laminate may be planarized as shown in FIG. 12c. The process of FIGS. 12a-c may also be used to realize mechanically stable ultra thick diamond laminate structures which may then be bonded to a thermal substrate and a thermally emissive device attached thereupon. In another embodiment, the use of a relatively thick, for example, 200 to 400 um thick, free standing diamond laminate may be used. The free standing diamond laminate may be attached to the final thermal heat sink or may be attached to a temporary substrate for processing. Other methods of patterning a free standing diamond laminate can include micromachining and EDM or any other suitable method of patterning a laminate.

In applications with thick film diamond and free standing diamond thick films, the diamond laminate may be bonded to a substrate, and patterned and etched by a laser, for example. Copper may then be plated up around the laminate. Planarization may proceed subsequently, as desired or required. Alternatively, the patterned diamond laminate may be aligned with a patterned copper wafer such that the pattern of the laminate and the pattern of the copper wafer interlock and can be bonded together with mechanical integrity. Alternatively, the patterned diamond laminate may be pressed into a metal wafer, which may then be heated. In these and other ways, the thick film laminate of diamond, in combination with a metal form, may be made to have a generally average CTE and may be made to be conductive, similar to what may be accomplished using integrated wafer level processes, as previously described. The methods of making the heat spreaders of the present disclosure described herein are not limiting, and any suitable method of making the heat spreaders described herein may be used.

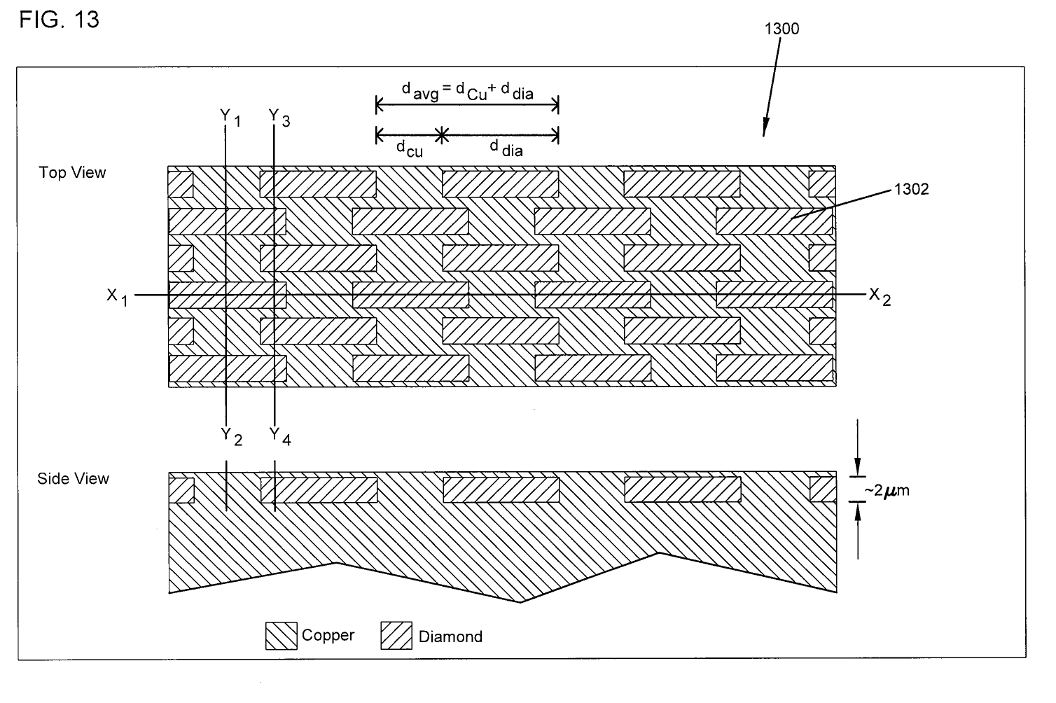

As referenced above, some embodiments of heat spreaders according to the present disclosure may include anisotropic properties in the plane of attachment of the thermally emissive device. For example, FIG. 13 shows a plan view of an embodiment of a heat spreader 1300 in which the thermal properties in the plane of device attachment are anisotropic. As may be seen from FIG. 13, the heat spreader 1300 can include elongated regions 1302 of high-TC diamond along the X-direction. Accordingly, the TC of the heat spreader may be higher along the X-direction than the Y-direction in the plane of device attachment. The diamond regions 1302 are shown as rectangles, though any suitable shape and dimension are within the scope of the invention, and rectangles are used only to illustrate an example of anisotropic embodiments. In the embodiment illustrated, a generally isotropic CTE plane may be maintained, which may be an advantageous design criteria for matching many thermally emissive device materials.

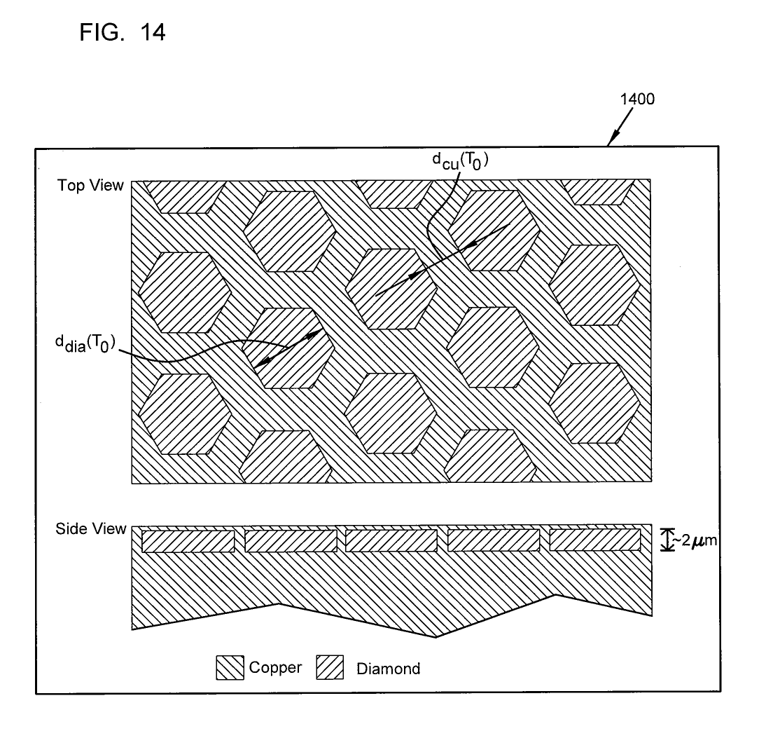

FIG. 14 illustrates one specific embodiment of a wafer level, patterned composite structure 1400 according to the present disclosure. Particularly, FIG. 14 illustrates a bulk composite structure where near isotropic thermal conductivity in the plane of component attachment may be provided. In the embodiment shown, a CTE that is generally relatively near that of GaAs may be achieved. For example, the width of a copper region, d_{Cu}(T₀), may be about 0.45 times the width of a diamond region, d_{dia}(T₀). However, these relative dimensions are provided as an example only, and other relative dimensions may be used.

In addition to thermal management, in some applications, such as for integrated circuits or vertical cavity laser arrays, a heat spreader according to the present disclosure may have a patterned diamond layer underneath the device area that may generally relatively match the CTE of the device, such as described above, and in other regions, the patterned diamond layer may form non-electrically conductive traces, such that input/output (I/O) traces may then be deposited and fabricated upon the non-electrically conductive diamond traces so that I/O functions may become a part of the surface of the heat spreader, in addition to spreading the heat load.

What has been disclosed is a novel, artificially structured material that may be built at wafer level or at a discrete device level, and that may use relatively thin films, thick films, or free standing laminates, for example. All embodiments may employ planar processing technologies such as patterning and etching and deposition technologies. A patterned surface composite heat spreader of the present disclosure may, in some embodiments, be used in wafer-to-wafer bonding or be used in chip-to-chip or device level bonding. It may be used in single device level, device row-bar level, or multiple device level bonding. In the former case, a wafer level heat spreader may be matched to a wafer of devices, and in the latter cases, heat spreaders may be singulated to match a specific device or device array. In some embodiments of the present disclosure, wafer level processing and advanced semiconductor manufacturing techniques may be used to achieve vertical manufacturing scales and economies. Some embodiments of the present disclosure may be used to heat sink to a passive thermal reservoir, while other embodiments of the present disclosure may be used to heat sink to an active thermal reservoir.

In addition to embodiments of the present disclosure providing novel and advantageous heat spreading devices and methods which may be used to replace prior art heat spreaders, some embodiments of the present disclosure may be used in conjunction with prior art active technologies, which technologies by themselves may suffer from material limitations at the interface between the device and the heat spreading structure proper. Using embodiments of the present disclosure together with prior art heat spreaders may allow the patterned surface composite heat spreader of the present disclosure to be used as a sub-mount that connects the thermally emissive device to an active cooler. Additionally, in other embodiments, the patterned surface composite heat spreader may be fabricated directly upon the surface of an active cooler system. In some embodiments, multi-physics modeling tools may simultaneously model the stress-strain as a function of thermal loading. Similarly, multi-physics finite-element analysis modeling may also be used to optimally characterize the heat spreader system.

Although the present invention has been described with reference to preferred embodiments, persons skilled in the art will recognize that changes may be made in form and detail without departing from the spirit and scope of the invention. For example, while generally described as a patterned composite structure of Cu—W, it is recognized that any other suitable materials or combinations of materials may be used to make the patterned composite structures of the present disclosure, and the patterned composite structure of the present disclosure is not limited to just Cu—W composites. Further, while some embodiments are described comprising two materials, such as Cu—W, it is recognized that more than two materials may be used to form a heat spreader and are within the scope of the present disclosure.

We claim:

1. A patterned surface composite structure comprising:
a first material having a first coefficient-of-thermal-expansion; and
a second material having a second coefficient-of-thermal-expansion;
wherein the first material is patterned with features and the second material is located between the features, thereby forming areas having a coefficient-of-thermal-expansion between that of the first and second materials.

2. The patterned surface composite structure of claim 1, wherein the first material is diamond.

3. The patterned surface composite structure of claim 2, wherein the second material is copper.

4. The patterned surface composite structure of claim 1, wherein the features are generally polygonal.

5. The patterned surface composite structure of claim 4, wherein the features are generally hexagonal.

6. The patterned surface composite structure of claim 3, having a generally smooth surface for receiving a thermally emissive device.

7. The patterned surface composite structure of claim 1, further comprising areas defining a plurality of heat spreaders, capable of being independently removed from the structure.

8. The patterned surface composite structure of claim 1, further comprising an area defining an electrically conductive path.

9. The patterned surface composite structure of claim 1, further comprising a conductive path over non-conductive traces wherein the conductive path carries input/output or power for a thermally emissive device attached to the structure.

10. A thermally emissive structure comprising:
a heat spreader structure comprising:
a first material having a first coefficient-of-thermal-expansion; and
a second material having a second coefficient-of-thermal-expansion;
wherein the first material is patterned with features and the second material is located between the features, thereby forming a structure having a coefficient-of-thermal-expansion between that of the first and second materials; and
a thermally emissive device mounted to the heat spreader.

11. The thermally emissive structure of claim 10, wherein the thermally emissive device is a laser diode.

12. The thermally emissive structure of claim 10, wherein the thermally emissive device is a monolithic microwave integrated circuit (MMIC).

13. The thermally emissive structure of claim 10, wherein the thermally emissive device is a power FET.

14. The thermally emissive structure of claim 10, wherein the thermally emissive device is a microprocessor.

15. The thermally emissive structure of claim 10, further comprising an area defining an electrically conductive path.

16. The thermally emissive structure of claim 10, further comprising a conductive path over non-conductive traces wherein the conductive path carries input/output or power for a thermally emissive device attached to the structure.

17. A method of making a patterned composite structure comprising:
depositing a first material having a first coefficient-of-thermal-expansion;
patterning features in the first material; and
depositing a second material having a second coefficient-of-thermal-expansion over the first material.

18. The method of claim 17, further comprising planarizing the structure such that a surface of the structure comprises areas of the first material and areas of the second material.

19. The method of claim 18, further comprising defining a plurality of heat spreaders in the surface.

20. The method of claim 17, wherein the first material is diamond.

21. The method of claim 20, wherein the second material is copper.

22. The method of claim 18, further comprising attaching a thermally emissive device to the surface.
